(19) United States
(12) Patent Application Publication
(10) Pub. No.: US 2008/0020547 A1
(43) Pub. Date: Jan. 24, 2008

(54) Method Of Transferring At Least One Object Of Micrometric Or Millimetric Size By Means Of A Polymer Handle

(76) Inventors: Marek Kostrzewa, Grenoble (FR); Lea Di Cioccio, St Ismier (FR); Marc Zussy, St Egreve (FR)

Correspondence Address: HAYES SOLOWAY P.C., 3450 E. SUNRISE DRIVE, SUITE 140, TUCSON, AZ, 85718, US

(21) Appl. No.: 11/576,136

(22) PCT Filed: Oct. 18, 2005
(86) PCT No.: PCT/FR05/50863

§ 371 Date: Mar. 27, 2007

(30) Foreign Application Priority Data
Oct. 21, 2004 (FR) 0452393

(51) Int. Cl. H01L 21/46

(52) U.S. Cl. 438/458; 257/E21.482

(57) ABSTRACT

The invention concerns a method for transferring at least one object of micrometric or millimetric size onto a host substrate by means of a handle. The method comprises the following steps: fixing a polymer handle on said object in order to be able to obtain a structure, constituted of the handle and the object superimposed, and deformable, surface preparation of the face of the object opposite the handle with a view to its adhesion on a face of the host substrate, bringing into contact and adhesion of said face of the object on said face of the host substrate after deformation of at least the handle, removal of the polymer handle.

### TECHNICAL FIELD

The invention concerns the use of a polymer handle to manufacture, clean and maintain vignettes, electronic circuits or other objects of micrometric or millimetric size before transferring them onto a destination substrate and integrating them with said substrate by molecular adhesion or by another bonding technique.

The invention relates, in particular, to the field of the heterogeneous integration of photonics on silicon and principally concerns the collective manufacture of chips and/or vignettes of silicon, of InP and/or of another material in order to transfer them onto a substrate known as a host substrate. It is also possible to use this invention for a transfer and a collective technological treatment of any other object, even a thin film.

### STATE OF THE PRIOR ART

Intra-chip or inter-chip electrical Interconnections become a very important limitation in pursuing the miniaturisation and increasing the performance of integrated circuits. The causes of the predictable limitations are the increase in the propagation times in the lines and the electrical consumption of the line amplifiers and concern the timing distribution and the longest signals or groups of signals. Optical solutions must potentially enable these obstacles to be lifted. However, they imply a considerable research effort in the field of the technology.

It is indispensable to take an interest in the replacement of a certain number of electrical links (the first of them being the timing signal) by optical links. Several studies have shown that the timing signal distribution in a system controlled by one or several processors consumes around 40% of energy even if said system does not run any programme, which leads to the very considerable dissipation of power and consequently firstly does not enable a greater miniaturisation and secondly makes it necessary to design cooling circuits, the concept of which is often awkward for the proper operation of the system. In any event, the integration of several levels of metallization and miniaturisation become technologically more and more difficult or even impossible.

One solution is to replace part of the timing distribution electronic circuit by optical distribution (consequently, one will obtain a reduction in metallization levels). The principles of this idea are as follows: optical wave guides located above the CMOS components convey information between photonic emitters and receivers (micro-laser source and detector). Since the detectors are localised in H-TREE structure, no delay between the detectors is generated. In the zones neighbouring the detector localisation, the signal distribution takes place by means of metallic interconnections.

In order to assure this electro-optical coupling, it is necessary to know how to integrate heterostructures of III-V materials by epitaxy on silicon substrate for example. This integration is indispensable because only alloys in III-V material (In, Ga, As, P) enable high performance optoelectronic components to be formed. On the other hand, since technology on silicon is well known and developed, it makes it possible to link up the technological methods of manufacturing optical interconnections.

Indeed, the technology of transferring thin films enables this type of hetero-structure to be obtained by “full wafer” molecular bonding. One may refer to this subject in the book “Wafer bonding: Applications and Technology”, Springer 2004, chapter 7, published by U. Gösele and M. Alexe.

Since the optoelectronic components are localised in very precise places on the CMOS component and since they have a size close to several tens of micrometres squared, one is therefore interested more particularly in the transfer of vignettes of the size of a component rather than the transfer of a layer of the diameter of a substrate. It is obvious that the transfer of vignettes is a lot more advantageous economically than the transfer of entire substrates. On the other hand, the molecular bonding of vignettes requires a particular preparation.

Different bonding Technologies exist for chip transfer such as bonding by epoxy adhesive, eutectic welding or bonding by “flip-chip” technology. The choice of bonding technology depends on the desired application.

Each type of bonding assures different properties of the bonding interface (thermal and electrical conductivity, thermal stability, transparency to certain wavelengths, etc.). In the case of chip molecular bonding, said bonding consists in preparing two surfaces so that a simple bringing into contact at ambient temperature is sufficient to assure a very good adhesion.

The bonding technique must be compatible with the chip transfer technique. At present, only “pick and place” technology enables both a sequential and automated individual transfer of chips. Before beginning the “pick and place” sequences the substrate is bonded onto an adhesive film and the chips are prepared by separation techniques.

In a standard procedure of preparation of chips, the wafer is first bonded onto an elastic tape. The separation of chips is obtained by a mechanical sawing and/or by laser, chemical etching, ionic etching or other. The chips are ready to be transferred onto another substrate after having been separated.

Concerning mechanical sawing, a cutting machine enables the substrate to be cut into square chips. The substrate to be cut is bonded to a plastic film that assures it mechanical strength. The depth of the cutting can vary from several micrometres up to the total thickness of the substrate. One may thereby control the depth of the cutting and cut the entire substrate or just “pre-cut” it. The machine makes it possible to index the distances between the saw cuts, which enables an automatic cutting to be carried out. The cuts are possible in two directions (parallel and perpendicular). In this respect, one may consult U.S. Pat. No. 6,500,047.

Another cutting technique is disclosed by U.S. Pat. Nos. 6,676,491 and 6,709,953. This thin chip preparation technique consists in cutting a semi-conductor substrate into several squares of desired size. The cutting takes place over a thickness less than the thickness of the substrate. During the cutting action, the depth of sawing can vary from several tens of micrometres up to the total thickness of the substrate. Since the substrate is sawed over a depth less than its thickness, it is possible to bond a plastic film onto the sawn face. The chips may be freed by grinding, in other words by thinning on the rear face of the wafer or they are prepared on the front face. The removal of the material stops at the moment of the separation of the chips. The plastic film bonded beforehand assures the mechanical strength. In order to obtain a low roughness of the rear face it is possible to use suitable rectification tools.

Depending on the requirements, another plastic film may be bonded onto the rectified face of the chips and the first plastic film may then be removed. This makes it possible to expose the front face of the chips, and, depending on the requirements, bond them onto a destination substrate by the front face or by the rear face. The separated chips may be transferred by means of a suction machine (“pick and place” technique).

The chips are then brought onto the wafer where they have to be fixed by tools known as hybridation tools. At present, the “pick and place” type machine is the most widely known hybridation tool. In order that the head of the “pick and place” machine can suck up the chip (pick it up) and in order to facilitate the disbondment of the chip from its tape, one may use a “stylet”. Said stylet raises the chip through the plastic film (by the rear face).

The stylet (or the multi-stylet) can pierce this film and disbond the chip or raise the chip by deforming the plastic film but without deteriorating it. The stylet may be replaced and/or reinforced by an air jet or a water jet. On the other hand, the use of this type of tool can damage the chips or the vignettes when they are thin.

The disbondment of the chips may also be obtained thanks to the specific properties of plastic films. One may locally heat the plastic film and in this case the film must be sensitive to the heat treatment (see U.S. Pat. No. 5,893,746). One may also use UV radiation to locally expose a film sensitive to UV. This treatment locally changes the adhesion of the film and facilitates the disbondment of the chip.

DBG (Dicing Before Grinding) technology requires the use of plastic films having different properties because most of the time the chips are manipulated at each of these steps by bonding them onto tapes.

Depending on the applications and/or steps, the plastic films assure a greater or lesser adhesion. They can change their adhesion as a function of the temperature, the exposure (UV), etc. The disadvantages of tapes are most often only withstanding a single operation and, in particular, plastic films do not withstand chemical and heat treatment at the same time.

The individual transfer of chips therefore takes place by the “pick and place” technique.

In order to bond a chip onto a substrate, the head of the “pick and place” machine comes into contact with the chip to be transferred. Thanks to the suction system, the chip disbonds from its tape and is placed on the destination substrate on which a layer of adhesive (normally an epoxy adhesive) is deposited. The disbondment of the chips is possible thanks to the physical properties of the tapes (their adhesion as a function of the temperature, the exposure, etc.).

In the assembly of chips, one most often uses epoxy adhesives. The bonding techniques via this type of adhesive do not enable the thickness of the adhesive to be perfectly controlled, which can locally change the transmission of light. Moreover, the maximum temperature of a heat treatment of the structures thus bonded is limited. However, for assembly applications, this technique is all the same very efficient. The chip transfer machine is equipped with a system enabling a deposition of the epoxy adhesive or a resin to be carried out.

The other bonding techniques (metallic, alloying, polymer, etc.) do not assure the desired bonding interface (interface transparent to light, thin, etc.) in terms of optical interconnections.

For applications in the field of optical interconnections, said limitations have to be resolved. The use of the molecular adhesion method is a promising means for attaining the objectives of 3D integration because it makes it possible to obtain very thin bonding interfaces, transparent to light and because it is compatible with heat treatments, even at high temperatures. Finally, it is a generally well mastered technique.

Molecular bonding requires a specific preparation of the faces to be assembled. The means used for the collective preparation of chips must withstand chemical preparation and mechanical-chemical polishing, or other types of treatment such as surface grafting, etc.

Concerning 3D integration (direct bonding) by “full wafer” type transfer, techniques exist enabling components (formed on a substrate) to be transferred onto a destination substrate (see in particular U.S. Pat. No. 6,627,531). The donor substrate, containing components or circuits, may be planarised and bonded onto another substrate by molecular adhesion (technique known as “wafer bonding”). Then, it is possible to mechanically thin the donor substrate by its rear face. Even for a localised transfer of components, this technique imposes the transfer of an entire wafer.

Another technique, disclosed in the document WO-A-03/081664, is based on the use of a handle. Here, the embrittled zone is formed in the donor substrate containing the components. Then, the assembly of said donor substrate on another substrate known as handle substrate takes place by bonding with an adhesive that enables an easy disbondment. The donor substrate is then separated by cleavage along an embrittled zone. One obtains a handle substrate with a thin film containing the components to transfer. The use of a handle substrate (or stiffener) enables the preparation of a thin surface for the final bonding on a destination substrate. After this bonding, the handle substrate may be removed easily. Since the handle is rigid, the transfer takes place in a collective manner, in other words that all of the components are transferred simultaneously.

The document WO-A-02/082 502 discloses a selective transfer method of at least one element from an initial support onto a final support. This method comprises the steps consisting in manufacturing chips on an initial substrate, planarising the initial substrate with the chips, transferring said substrate onto another stiffening handle substrate, eliminating the initial substrate, separating the chips and embrittling the handle substrate around the chips to be transferred (by chemical etching for example). This embrittlement enables the selective prehension of the chips, because the embrittled zones break under pressure, or under aspiration and the removed chip may be placed and fixed onto a final substrate. The disadvantages of this technique are as follows: after each removal of the chip, the handle substrate (stiffener) becomes more fragile, the handle substrate in breaking (by cleaving) produces particles that can be bothersome for the continuation of the molecular bonding technology.

### DESCRIPTION OF THE INVENTION

To overcome the disadvantages of the prior art, the present invention proposes a transfer method using a polymer handle as self-supporting substrate, enabling the mechanical strength of vignettes, chips, wafers, thin films or other objects of micrometric or millimetric size to be assured.

The subject of the invention is therefore a method for transferring at least one object of micrometric or millimetric size onto a host substrate by means of a handle, characterised in that it comprises the following steps:

fixing a polymer handle on said object in order to be able to obtain a structure, constituted of the handle and the object superimposed, and deformabie, comprising the deposition of the polymer in the liquid state on said object and the polymerisation of the polymer,

surface preparation of the face of the object opposite the handle with a view to its adhesion on a face of the host substrate,

bringing into contact and adhesion of said face of the object on said face of the host substrate after deformation of at least the handle,

removal of the polymer handle.

According to a first embodiment, if the transfer concerns a plurality of vignettes formed in a thin film integral with an initial substrate, a step of pre-cutting the vignettes before the fixing of the polymer handle and a step of elimination of the initial substrate up to obtaining vignettes separated from each other is provided for, the step of bringing into contact and adhesion of a vignette being obtained after deformation of the handle in the direction of the superposition. Advantageously, the step of bringing into contact and adhesion of a vignette comprises the use of a stylet to lay flat said vignette on the face of the host substrate. According to another particular aspect, if the object is a thin film relaxed by crimping on an initial substrate, a step of elimination of the initial substrate after the step of fixing of the handle on the thin film is provided for, the step of bringing into contact and adhesion of the thin film being obtained after deformation of the structure in the superposition plane.

According to a second embodiment, the transfer concerns a plurality of vignettes cut and already separated from an initial manufacturing substrate, the fixing of the polymer handle taking place by bonding of a first face of the vignettes on the handle, the step of bringing into contact and adhesion of a vignette being obtained after deformation of the handle in the direction of the superposition. Advantageously, the step of bringing into contact and adhesion of a vignette comprises the use of a stylet to lay flat said vignette on the face of the host substrate.

The polymer of the handle is advantageously PDMS.

The adhesion of said face of the object on said face of the host substrate may be an adhesion by molecular bonding.

The removal of the polymer handle may comprise the deformation of the handle.

### BRIEF DESCRIPTION OF DRAWINGS

The invention will be more fully understood and other advantages and specific features will become clear on reading the description that follows, given by way of example and in nowise limitative, along with the appended drawings, among which:

FIGS. 1A to 1D illustrate steps of a method for transferring chips, according to the present invention,

FIGS. 2A to 2F illustrate steps of a method for transferring a thin film having a complicated morphology, according to the present invention,

FIGS. 3A to 3C illustrate steps of a method for transferring chips already cut, according to the present invention.

### DETAILED DESCRIPTION OF SPECIFIC EMBODIMENTS

The invention enables in particular the manufacture of electronic chips in a collective manner by taking into account the specific character of the objects to be bonded and particularly the surface preparation (vignettes of small size, fragility of the material, bonding interface of low thickness, chemical preparation, mechanical surface treatment, etc.).

According to a preferred embodiment of the invention, before preparing a handle, the chips formed on the surface of a substrate are pre-cut mechanically or by chemical and/or plasma etching. The depth of the etching or the cut of the saw blade roughly determines the final thickness of the transferred vignettes, said vignettes being able to be thinned subsequently.

On the pre-cut vignettes or chips, one deposits a polymer in the liquid state. Said polymer is advantageously polydimethylsiloxane (PMDS) or any other polymer having similar or close properties. The polymer being a viscous material, the spreading is achieved spontaneously or by means of a spin coater. In both cases, the polymer penetrates the spaces between the vignettes. The use of a spin coater leads to a greater homogeneity of deposition, but does not enable thicknesses greater than around 30 μm to be obtained. In order to obtain a homogenous and thick deposition at the same time, one solution consists in carrying out the deposition several times.

The Dow Corning Company, which supplies PDMS, gives the following properties for its product SYLGARD®184:
On delivery:
   viscosity at 23° C.: 5500 mPa·s
      mixing ratio by weight (base/polymerisation agent): 10/1
   viscosity at 23° C. immediately after mixing with the polymerisation agent: 4000 mPa·s
   pot life at 23° C.: 2 hours.
Physical properties after polymerisation for 4 hours at 65° C.:
   colour: transparent
   Shore A (Durometer) hardness: 50
   tensile strength: 7.1 MPa
   elongation at break: 140%
   tear strength—B punch: 2.6 kN/m
   density at 23° C.: 1.05
      volumic thermal expansion coefficient: 9.6 0.10⁻⁴/K
   coefficient of thermal conductivity: 0.17 W/m.K.

In order to obtain good homogeneity after spreading of the polymer, a wafer (for example in silicon) may be placed on the layer of polymer poured onto the chips. The homogeneity of the distance between the wafer and the substrate supplying the vignettes may be assured by support through the intermediary of wedges the thickness of which is chosen as a function of the requirements.

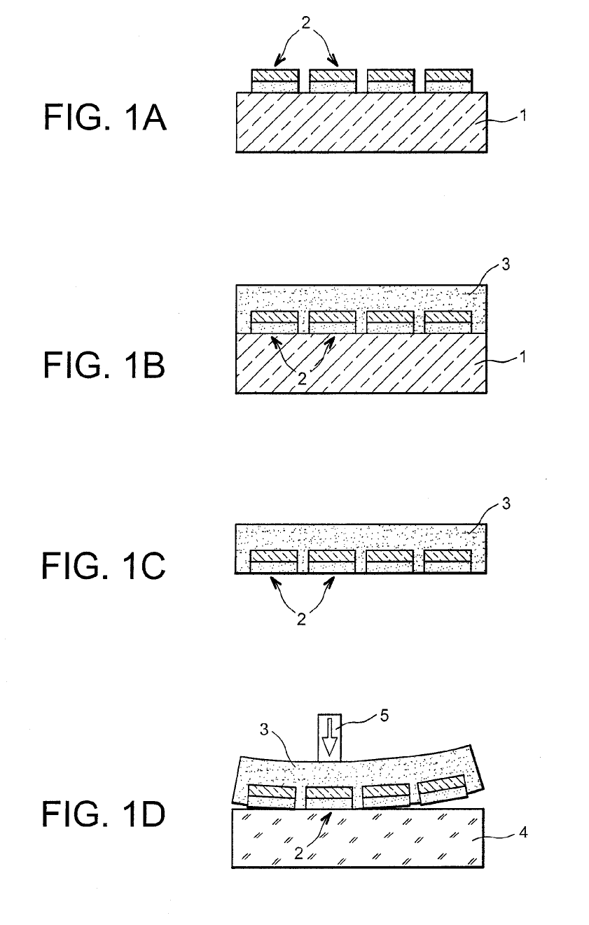

FIGS. 1A to 1D illustrate steps of a method for transferring chips according to the present invention.

FIG. 1A shows, in a side and section view, a substrate 1 (for example in silicon or in InP) on a face from which chips 2 have been manufactured and pre-cut, for example by mechanical saw. The chips have for example a section of 2 mm×2 mm and a thickness of 100 μm. The thickness of the pre-cut can vary from the initial thickness of the substrate up to ten or so micrometres.

FIG. 1B shows the structure obtained after the deposition, by spin coater or by direct deposit, of the polymer PDMS. The thickness of the polymer is chosen equal to 520 μm. This thickness makes it possible to obtain a good mechanical strength of the vignettes and a sufficient elasticity of the polymer for the remainder of the method. The deposition of the polymer may take place directly on the wafer assuring the homogeneity of the thickness so that its removal takes place directly.

One then carries out a degassing and a polymerisation annealing. The supplier of PDMS declares that the polymerisation of a precursor and a pre-polymer takes place at ambient temperature or at the annealing temperature. After polymerisation, the substrate supplying chips is removed mechanically (for example by grinding) up to the thickness corresponding to the separation of the vignettes or even slightly less than this value. In this latter case, the separation of the vignettes will take place during the remainder of the preparation.

FIG. 1C shows the structure thereby obtained. The rear face of the chips (that opposite the polymer) has been polished in order to obtain well separated chips. One thereby obtains a self-supporting polymer substrate or handle, smooth on one side and with vignettes in a mosaic pattern on the other side.

Since the surface of the polymer is smooth, this handle may be maintained as a substrate in silicon. The polymer effectively protects one face of the vignettes or chips and enables at the same time a preparation of the other face of the vignettes in a collective manner. This preparation may consist:
in applying a chemical preparation (acids, bases, solvents chemistry), the polymer PDMS resisting chemical treatments (such as H₂SO₄, H₂O₂, ammonia, TMAH) well;
in treating the surface with a plasma or a UV radiation;
in carrying out depositions of oxide layers;
in carrying out any other preparation enabling a molecular or other bonding to be performed.

This preparation obviously has to be compatible with the temperature resistance of the polymer (typically less than 200° C.).

In certain cases, a polishing making it possible to obtain a suitable roughness is necessary.

Since the handle in polymer is elastic, it may be mounted on a suitable collar and may be slightly strained in order to increase the separation distance between the vignettes and to enable them to be disbonded in an even easier manner.

The handle 3 is then placed above the host substrate 4 (see FIG. 1D) on which one or several vignettes have to be bonded. The host substrate is advantageously placed on a micrometric table. The positioning of the vignettes may be carried out with the desired precision and may be followed by an infrared camera. A stylet 5 presses on and deforms the handle 3 at the place corresponding to the centre of the vignette to be transferred. The polymer deforms whereas the vignette, which is rigid, does not follow this elastic deformation. The disbondment of the chip then takes place. As soon as the vignette comes into contact with a substrate, the phenomenon of molecular bonding takes place. The chip disbonds entirely from the polymer handle. The stylet is raised, the polymer being elastic returns to its initial shape and the substrate moves. The action (cycle) of disbondment of the chip may begin again. It is important to underline that this stylet may have a different geometric shape and may be composed of one or several points. If necessary, it may be replaced by a water jet, an air jet. It may comprise a heating or cooling system, a displacement and rotation system.

Once all of the molecular bondings have been carried out, the refinement of the positioning may be achieved by the chemical etching of the vignettes. Since the vignettes transferred are bigger than the surface necessary in order that the component can be manufactured, one may thereby eliminate the material if necessary.

The major advantage of the polymer handle compared to an adhesive tape is that the tapes are dedicated to a unique and well defined use such as sawing, transfer, grinding. It is not possible to find a tape that can at the same time resist thinning, chemical treatment, UV treatment and/or heat treatment for the collective preparation of chips, and then be used as handle enabling the transfer of chips.

The polymer handle may be used in the case where the vignettes have reliefs or in the case where the morphology of the surface or the topology does not enable an adhesive tape to be used. Given that the polymer is liquid at the moment of deposition, it adapts easily to the topology of the objects to be transferred. One may therefore use this technique for a transfer and/or a surface treatment of any sort of object of micrometric size in which the topology of the rear face is complicated. Depending on the application, the handle may be used with or without stiffening support. A stiffening support may be useful for a grinding or a polishing operation and useless for a chemical treatment or an exposure.

The handle according to the invention may also be used to carry out a transfer of wafer or layers having dimensions (in the longitudinal sense) greater than the vignettes or chips, in particular for the transfer of deformed thin films and having a particularly complicated morphology. It has been demonstrated that compressive stressed thin films, deposited on a viscous material, relax by crimping. The use of a polymer such as PDMS may be employed in order to planarise and transfer such a thin film onto a host substrate.

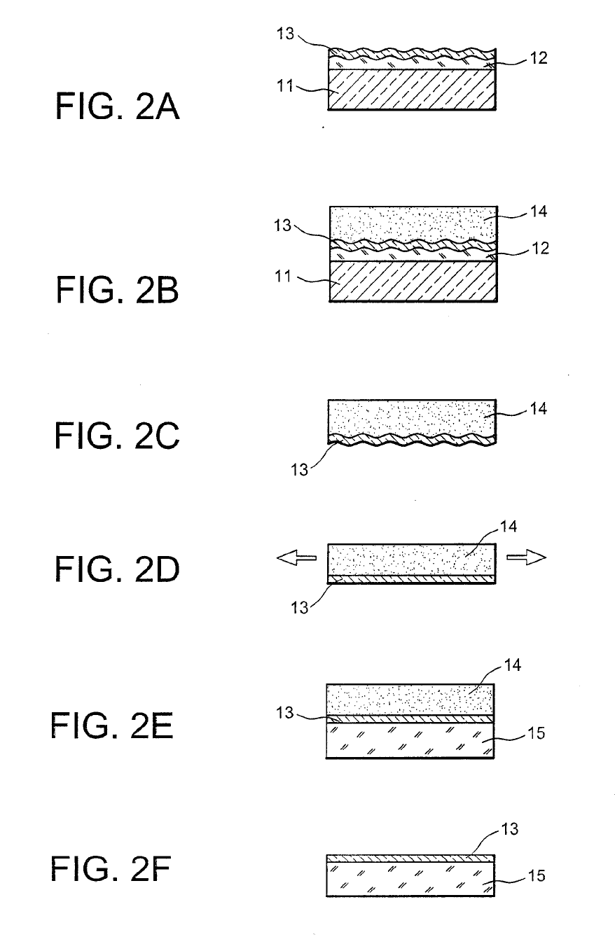

FIGS. 2A to 2F illustrate steps of a method for transferring a thin film having a complicated morphology, according to the present invention.

FIG. 2A shows, n side and sectional view, a substrate 11 (for example in silicon) bearing successively a viscous layer 12 (for example in glass, in wax, in resin or in another polymer) and a thin film 13 of 30 nm thickness for example (for example in SiGe or in III-V material). The thin film 13 has a complicated morphology due to the fact that this thin film was a layer initially compressive stressed and that is relaxed by crimping in the presence of the underlying viscous layer 12.

FIG. 2B shows the structure of FIG. 2A on which a layer of PDMS 14 forming a handle has been deposited on the thin film 13.

The substrate 11 and the viscous layer 12 are then removed to only leave remaining the thin film 13 adhering to the handle 14 (see FIG. 2C). The substrate may for example be removed by elimination of the viscous layer, this elimination takes place for example in a suitable solvent or by heating or even by chemical attacks, depending on the material of the viscous layer.

At this stage, the thin film 13, which relaxed by crimping, can slacken since the polymer handle 14 may be deformed, its low thickness and the low thickness of the thin film enabling it (see FIG. 2D). It is also possible, as a variant, to slacken the thin film 13 by an external mechanical action for example by means of a suitable collar, as described above.

The slackened thin film 13 is then bonded to a host substrate 15 (see FIG. 2E) and the polymer handle is then removed (see FIG. 2F), for example by mechanical disbondment from an edge or instead by plasma etching.

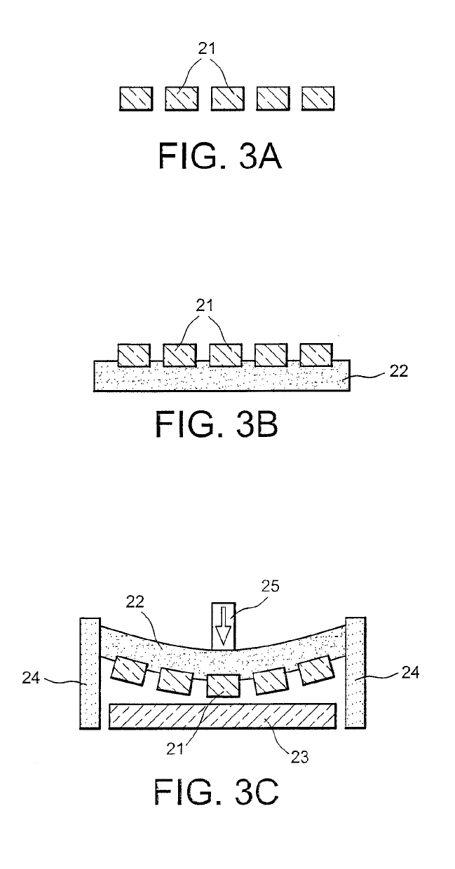

The polymer handle according to the invention may also be used to prepare and bond pre-cut vignettes. This is shown in FIGS. 3A to 3C.

FIG. 3A shows, in side view, vignettes 21 (for example chips in InP) already cut and separated.

FIG. 3B shows the vignettes 21 bonded onto a layer 22 of PDMS by their rear face. To do this, one may provide for a support in solid PDMS (already polymerised) of typically one to several hundred micrometres and deposit on this support a thinner layer (typically of several micrometres) of viscous PDMS. The vignettes are then arranged on this layer where they sink in slightly. One then carries out the polymerisation of the viscous layer of PDMS, thereby assuring the cohesion of the assembly. The vignettes then undergo a preparation, for example chemical, to make them compatible with the subsequent bonding. The superimposed structure obtained is a structure deformable in the direction of the superposition.

FIG. 3C shows the deposition of a vignette 21 on a host substrate 23 for example a silicon substrate coated with a layer of silicon oxide. The deposition may be carried out by using vertical guides 24 playing the same role as the abovementioned collar and a stylet or pointer 25. The polymer handle 22 is deformed above the emplacement chosen for the vignette to be deposited. The bringing into contact of the vignette with the host substrate takes place. The molecular bonding is carried out and the vignette disbonds from the handle during the removal of said handle, the molecular bonding having an adhesion force greater than the bonding with the handle.

1-9. (canceled)

10: A method for transferring at least one object of micrometric or millimetric size onto a host substrate by means of a handle, comprising the following steps:
fixing a polymer handle on said object in order to be able to obtain a structure, constituted of the handle and the object superimposed, and deformable, comprising the deposition of the polymer in the liquid state on said object and the polymerisation of the polymer,
surface preparation of the face of the object opposite the handle with a view to its adhesion on a face of the host substrate,
bringing into contact and adhesion of said face of the object on said face of the host substrate after deformation of at least the handle., and
removal of the polymer handle.

11: The transfer method according to claim 10, wherein, the transfer concerning a plurality of vignettes formed in a thin film integral with an initial substrate, a step of pre-cutting of the vignettes before the fixing of the polymer handle and a step of elimination of the initial substrate up to obtaining vignettes separated from each other is provided for, the step of bringing into contact and adhesion of a vignette being obtained after deformation of the handle in the direction of the superposition.

12: The transfer method according to claim 11, wherein the step of bringing into contact and adhesion of a vignette comprises the use of a stylet to lay flat said vignette on the face of the host substrate.

13: The transfer method according to claim 10, wherein said object is a thin film relaxed by crimping on an initial substrate, a step of elimination of the initial substrate after the step of fixing the handle on the thin film is provided for, the step of bringing into contact and adhesion of the thin film being obtained after deformation of the structure in the superposition plane.

14: The transfer method according to claim 10, wherein, in the transfer concerning a plurality of vignettes cut and already separated from an initial manufacturing substrate, the fixing of the polymer handle being achieved by bonding of a first face of the vignettes on the handle, the step of bringing into contact and adhesion of a vignette being obtained after deformation of the handle in the direction of the superposition.

15: The transfer method according to claim 14, wherein the step of bringing into contact and adhesion of a vignette comprises the use of a stylet to lay flat said vignette on the face of the host substrate.

16: The transfer method according to claim 10, wherein the polymer of the handle is PDMS.

17: The transfer method according to claim 10, wherein the adhesion of said face of the object on said face of the host substrate is an adhesion by molecular bonding.

18: The transfer method according to claim 10, wherein the removal of the polymer handle comprises deformation of the handle.
